(19) United States
(12) Patent Application Publication
(10) Pub. No.: US 2018/0277727 A1
(43) Pub. Date: Sep. 27, 2018

(54) REFLECTIVE COATING FOR FLIP-CHIP CHIP-SCALE PACKAGE LEDS IMPROVED PACKAGE EFFICIENCY

(71) Applicants: Frederic S. DIANA, San Jose, CA (US); Thierry SMET, San Jose, CA (US); Gregory GUTH, San Jose, CA (US); Lumileds LLC, San Jose, CA (US)

(72) Inventors: Frederic S. DIANA, Santa Clara, CA (US); Thierry DE SMET, Sunnyvale, CA (US); Gregory GUTH, San Jose, CA (US)

(73) Assignee: Lumileds LLC, San Jose, CA (US)

(21) Appl. No.: 15/765,113

(22) PCT Filed: Aug. 31, 2016
(86) PCT No.: PCT/US2016/049770

§ 371 Date: Mar. 30, 2018

Related U.S. Application Data
(60) Provisional application No. 62/238,664, filed on Oct. 7, 2015.

(51) Int. Cl. H01L 33/60; H01L 33/46; H01L 33/48; H01L 33/50

(52) U.S. Cl. CPC H01L 33/60; H01L 33/46; H01L 2933/005; H01L 33/505; H01L 2933/0033; H01L 33/486

(57) ABSTRACT

A method includes forming a reflective layer (202) on a support (110) where the reflective layer (202) defines openings to the support, placing light-emitting diodes (LEDs) (102) through the openings onto the support (110), forming a non-planar secondary light-emitting layer (106) that conforms to the LEDs and the reflective layer (202), forming a planar optically transparent cap layer (108) over the secondary light-emitting layer, and singulating the LEDs into LED units.

### CROSS-REFERENCE TO RELATED APPLICATIONS

The present application claims priority to U.S. Provisional Patent Application No. 62/238,664, filed Oct. 7, 2015. U.S. Provisional Patent Application No. 62/238,664 is incorporated herein.

### FIELD OF THE INVENTION

The present disclosure relates to semiconductor light-emitting diodes (LEDs), and more particular to surface-mount technology (SMT) flip-chip chip-scale package (CSP) LEDs.

### BACKGROUND

An LED may be mounted on a printed circuit board (PCB) and produce approximately a Lambertian emission pattern. Some of the light may exit the LED downwards into the PCB and lead to light-output loss. Thus what is needed is an LED packaging technique that reduces such light-output loss.

### SUMMARY

In one or more examples of the present disclosure, a method includes forming a reflective layer on a support where the reflective layer defines openings to the support, placing light-emitting diodes (LEDs) through the openings onto the support, forming a non-planar secondary light-emitting layer that conforms to the LEDs and the reflective layer, forming a planar optically transparent cap layer over the secondary light-emitting layer, and singulating the LEDs into LED units.

### BRIEF DESCRIPTION OF THE DRAWINGS

In the drawings:

FIG. 1 illustrates a light-emitting diode (LED) unit in examples of the present disclosure;

FIG. 2 illustrates an LED unit in examples of the present disclosure;

FIG. 3 is a flowchart of a method for making the LED unit of FIG. 2 in examples of the present disclosure; and

FIG. 4 illustrates structures formed in the method of FIG. 3 in examples of the present disclosure.

Use of the same reference numbers in different figures indicates similar or identical elements.

### DETAILED DESCRIPTION

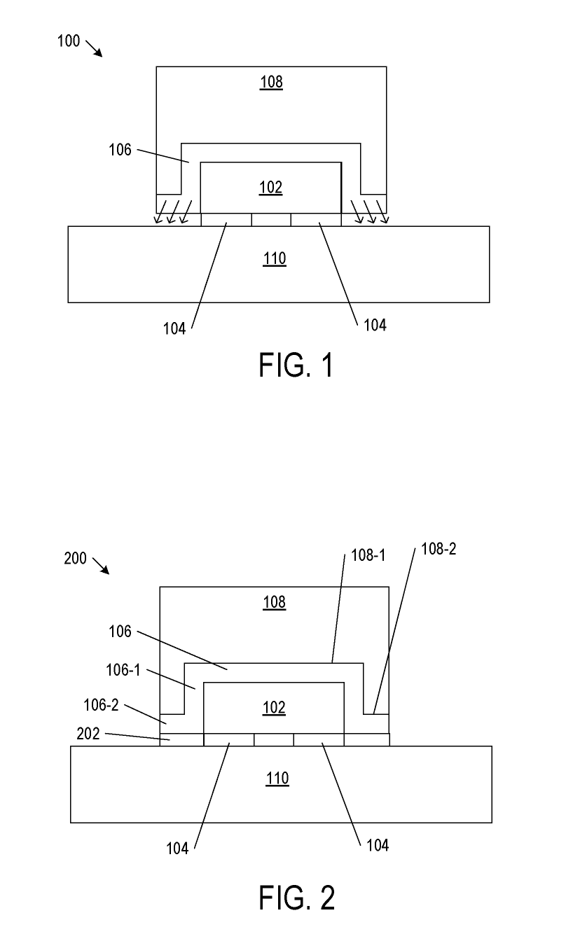

FIG. 1 illustrates a light-emitting diode (LED) unit 100 in examples of the present disclosure. LED unit 100 includes an LED 102 with bottom contacts 104, a secondary light emitter 106, and an optically transparent cap 108. LED unit 100 may be mounted on a printed circuit board (PCB) 110.

As can be seen, the light emitted by LED 102 may escape downward through secondary light emitter 106 and impinge PCB 110. The optical interaction between LED 102 and the PCB 110 may vary the color produced by LED unit 100 based on the PCB type. While dark or black ink coating on PCB 110 may be used to mitigate the LED-PCB optical interaction, it does not prevent light leakage into the PCB. Although a reflective coating on PCB 110 may be used to mitigate the light loss and color variation, it would make LED unit 100 dependent on the PCB surface reflectivity lifetime.

FIG. 2 illustrates an LED unit 200 in examples of the present disclosure. LED unit 200 includes LED 102 with bottom contacts 104, a reflector 202, secondary light emitter 106, and transparent cap 108. LED unit 200 may be mounted on PCB 110.

LED 102 may be a flip-chip chip-scale package (CSP) LED that emits light from all surfaces but a bottom surface with contact pads. LED 102 includes a top surface, lateral surfaces, and a bottom surface with contact pads 104. LED 102 typically has the shape of a rectangular prism but may be another shape such as a cube or a cylinder. LED 102 may have an area of 0.1 millimeter (mm) by 0.1 mm to 10 mm by 10 mm and a thickness of 10 microns (μm) to 1 mm.

Reflector 202 is located around the base of LED 102. Reflector 202 may be diffusive or specular. Reflector 202 may have the shape of a rectangular ring. Reflector 202 may have 90% reflectivity or better. Reflector 202 may be titanium oxide (TiOx) in silicone and have a thickness of 10 to 100 μm (e.g., 50 μm). Alternatively reflector 202 may be a mirror or specular films or tapes integrated by adhesives or applied by a coating processes.

Secondary light emitter 106 is located over reflector 202 and the top and the lateral surfaces of LED 102. Note that the use of the term “over” includes one element being directly atop another element. Secondary light emitter 106 may have the shape of a rectangular top hat with a crown 106-1 that receives LED 102 and a brim 106-2 that sits atop reflector 202. Secondary light-emitting layer 106 may be a laminate including a layer of TiOx (or another translucent or diffusive metal oxide) in silicone having a thickness of 10 to 300 μm, which makes the resulting LED unit 200 appear white in its off state, followed by a layer of phosphor in silicone having a thickness of 10 to 300 μm.

Transparent cap 108 is located over secondary light emitter 106. Transparent cap 108 may have the shape of a rectangular cap with an opening 108-1 that receives crown 106-1 of secondary light emitter 106 and a rim 108-2 that sits on brim 106-2 of the secondary light emitter. Transparent cap 108 may be silicone or glass. Transparent cap 108 may have a thickness of 0 to 10 mm (e.g., 675 μm).

As shown in FIG. 2, reflector 202 forms a backside coating on the brim of secondary light emitter 106 to prevent light from leaking into PCB 110. This configuration reduces color dependence on PCB type and avoids dark or reflective coating on PCB 110.

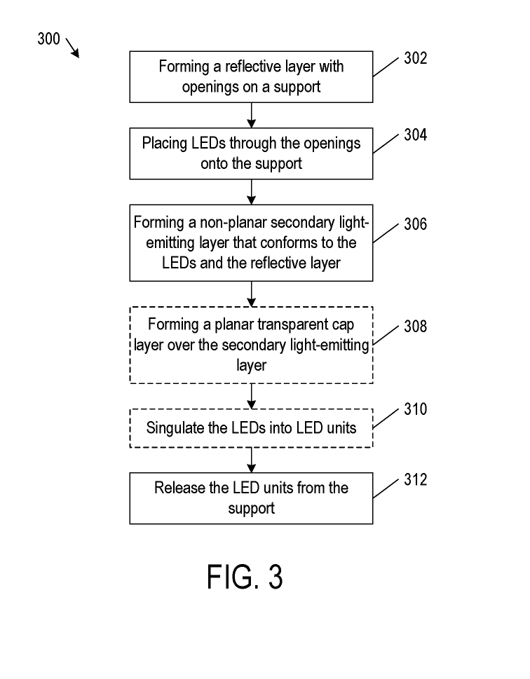

FIG. 3 is a flowchart of a method 300 for making LED unit 200 (FIG. 2) in examples of the present disclosure. Method 300 may begin in block 302.

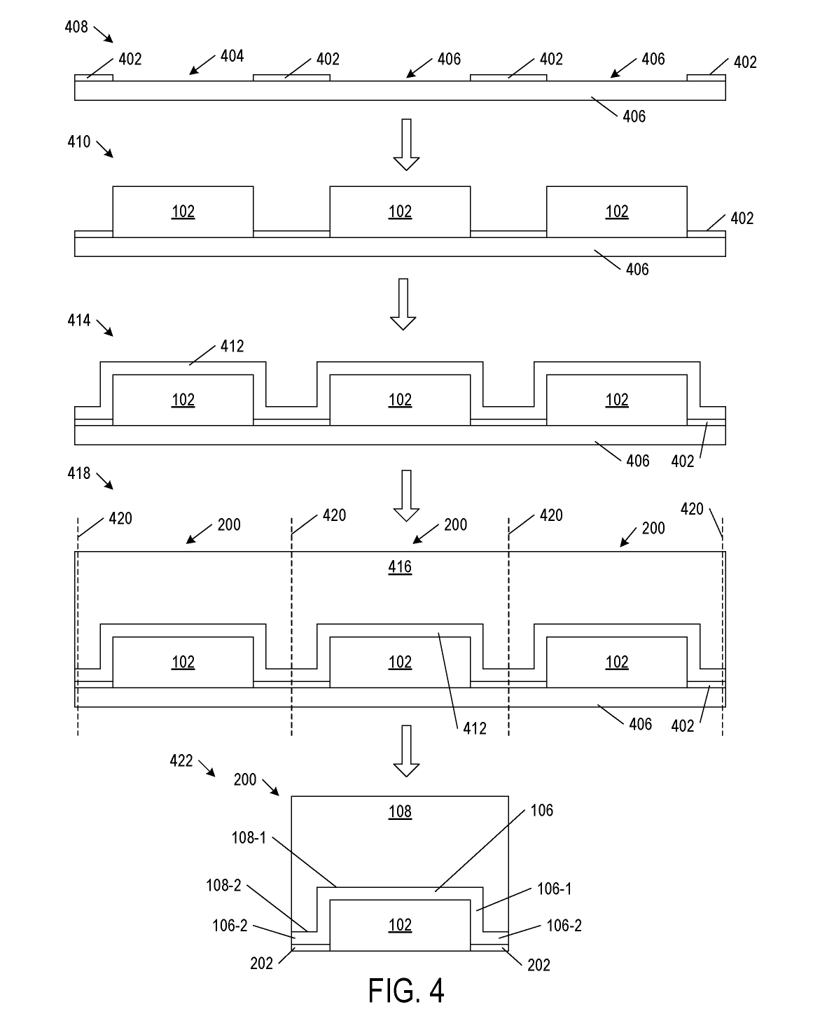

In block 302, a reflective layer 402 with openings 404 is formed on a support 406 as shown in view 408 of FIG. 4. Reflective layer 402 with opening 404 may be screen-printed onto support 406. Support 406 may be a tacky tape on a metal frame. Referring back to FIG. 3, block 302 may be followed by block 304.

In block 304, LEDs 102 are placed through openings 404 onto support 406 as shown in view 410 of FIG. 4. A pick-and-place machine may place LEDs 102 through openings 404 onto support 406. Referring back to FIG. 3, Block 304 may be followed by block 306.

In block 306, a non-planar secondary light-emitting layer 412 is formed over LEDs 102 and reflective layer 402 on support 406 as shown in view 414 of FIG. 4. Light-emitting layer 412 conforms to the topography of LEDs 102 and reflective layer 402 on support 406. Referring back to FIG. 3, block 306 may be followed by block 308.

In block 308, a planar optically transparent cap layer 416 is formed over secondary light-emitting layer 412 as shown in view 418 of FIG. 4. A molding machine may mold transparent cap layer 416 over secondary light-emitting layer 412. Referring back to FIG. 3, block 308 may be followed by block 310.

In block 310 LEDs 102 are singulated along scribe lanes 420 to form LED units 200 as shown in views 418 and 422 of FIG. 4. Referring back to FIG. 3, block 310 may be followed by block 312.

In block 312, LEDs units 200 are released from support 406. Heat may be applied to thermally release LED units 200 from support 406.

Various other adaptations and combinations of features of the embodiments disclosed are within the scope of the invention. Numerous embodiments are encompassed by the following claims.

1. A method, comprising:
forming a reflective layer on a support, the reflective layer defining openings to the support;
placing light-emitting diodes (LEDs) through the openings onto the support;
forming a non-planar secondary light-emitting layer that conforms to the LEDs and the reflective layer, the secondary light emitting layer having a rectangular top hat shape with a brim on the reflector and a crown that receives the LED;
forming a planar optically transparent cap layer over the secondary light-emitting layer, the planar optically transparent cap layer having an opening that receives the crown of the non-planar secondary light-emitting layer; and
singulating the LEDs into LED units.

2. The method of claim 1, further comprising releasing the LED units from the support.

3. The method of claim 1, wherein forming the reflective layer comprises screen-printing a layer of titanium oxide in silicone on the support.

4. The method of claim 1, wherein forming the secondary light-emitting layer comprises laminating a first layer of titanium oxide in silicone over the LEDs and the reflective layer and a second layer of phosphor in silicone over the first layer.

5. The method of claim 1, wherein forming the transparent cap layer comprises molding a layer of silicone over the secondary light-emitting layer.

6. A light-emitting diode (LED) unit, comprising: an LED, comprising:
a top surface;
lateral surfaces; and
a bottom surface with contact pads;
a reflector around a base of the LED;
a secondary light emitter over the reflector and the top and the lateral surfaces of the LED, the secondary light emitter having a rectangular top hat shape with a brim on the reflector and a crown that receives the LED; and
an optically transparent cap over the secondary light emitter, the optically transparent cap having an opening that receives the crown of the non-planar secondary light-emitting layer.

7. The LED unit of claim 6, wherein the reflector comprises titanium oxide in silicone.

8. The LED unit of claim 6, wherein the secondary light emitter comprises a laminate including a first layer of phosphor in silicone and a second layer of titanium oxide in silicone.

9. The LED unit of claim 6, wherein the cap comprises silicone.

10. The LED unit of claim 6, wherein the reflector forms a rectangular ring around the base of the LED.

11.-12. (canceled)
